(19) United States
(12) Patent Application Publication
(10) Pub. No.: US 2022/0416752 A1
(43) Pub. Date: Dec. 29, 2022

(54) CAPACITOR CIRCUIT OF A MULTI-BANK ARRAY TYPE AND A CAPACITANCE VARIABLE CIRCUIT HAVING THE SAME

(71) Applicant: SAMSUNG ELECTRO-MECHANICS CO., LTD., Suwon-si (KR)

(72) Inventors: Hyun PAEK, Suwon-si (KR); Sol-A KIM, Suwon-si (KR); Byeong-Hak JO, Suwon-si (KR); Jong-Mo LIM, Suwon-si (KR)

(73) Assignee: SAMSUNG ELECTRO-MECHANICS CO., LTD., Suwon-si (KR)

(21) Appl. No.: 17/780,071

(22) PCT Filed: Jul. 28, 2020
(86) PCT No.: PCT/KR2020/009948

§ 371 Date: May 26, 2022

(30) Foreign Application Priority Data
Dec. 6, 2019 (KR) 10-2019-0161733

(51) Int. Cl. H03H 7/38

(52) U.S. Cl. CPC H03H 7/38

(57) ABSTRACT

A multi-bank array type capacitor circuit is provided. The capacitor circuit includes a first cap bank including first to m^{th} switch-capacitor circuits which are connected in parallel with each other, wherein the first to m^{th} switch-capacitor circuits have different capacitances based on a first weight; and a second cap bank, connected in parallel with the first cap bank, and including first to m^{th} switch-capacitor circuits which are connected in parallel with each other, wherein the first to m^{th} switch-capacitor circuits have different capacitances based on a second weight that is different from the first weight.

### CROSS-REFERENCE TO RELATED APPLICATIONS

This application is a U.S. National Stage Application of International Application No. PCT/KR2020/009948, filed on Jul. 28, 2020, which claims the benefit under 35 USC 119(a) and 365(b) of Korean Patent Application No. 10-2019-0161733, filed on Dec. 6, 2019, in the Korean Intellectual Property Office, the entire disclosure of which is incorporated herein by reference for all purposes.

### BACKGROUND

### 1. Field

The following description relates to a capacitor circuit of a multi-bank array type and a capacitance variable circuit having the same.

### 2. Description of Related Art

Typically, bands of various frequencies may be implemented in a Radio Frequency (RF) field, and in a process of integrating these various frequency bands, it is becoming increasingly difficult and complicated to implement an antenna that can utilize all of these various frequency bands or multi-bands. Accordingly, it may be beneficial to implement a switch that converts impedance of the antenna.

Typically, when an array of capacitors is used to set various capacitance values, typically, a binary weighted method may be implemented.

However, the binary weighted method may not be suitable to tune capacitance for impedance tuning of the antenna.

A typical capacitor circuit of a multi-bank array type may include a binary weighted array capacitor that implements a binary weighted array, and although it is simple, a uniform distribution of capacitance is not uniform depending on an impedance matching frequency of the antenna. Because a frequency “f” and capacitance “c” have a relationship depending on the equation ‘

$$f = \frac{1}{2 π \sqrt{L \times C}} ,$$

when the frequency is tuned using the capacitance, a rough frequency distribution is shown as the frequency increases, and conversely a dense frequency distribution is shown as the frequency decreases.

Accordingly, for a typical capacitor circuit that tunes a frequency using a capacitance by implementing a binary weighted method, it may be difficult to uniformly tune when the frequency band changes, and thus there is a problem that tuning may not at a level that a user desires.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a multi-bank array type capacitor circuit includes a first cap bank including first to m^{th} switch-capacitor circuits connected in parallel with each other, wherein the first to m^{th} switch-capacitor circuits are configured to have different capacitances based on a first weight; and a second cap bank connected in parallel with the first cap bank, and including first to m^{th} switch-capacitor circuits which are connected in parallel with each other, wherein the first to m^{th} switch-capacitor circuits are configured to have different capacitances based on a second weight that is different from the first weight, wherein m is a natural number equal to or greater than 2.

Each of the first to m^{th} switch-capacitor circuits of the first cap bank may include a capacitor and a switch connected in series with each other, and wherein respective capacitors of the first to m^{th} switch-capacitor circuits of the first cap bank may be configured to have different capacitances based on the first weight.

Each of the first to m^{th} switch-capacitor circuits of the second cap bank may include a capacitor and a switch connected in series with each other, and wherein respective capacitors of the first to m^{th} switch-capacitor circuits of the second cap bank may be configured to have different capacitances based on the second weight.

The capacitor circuit may include a set of cap banks comprising the second cap bank to a n^{th} cap bank; wherein the n^{th} cap bank may be connected in parallel with the first cap bank or the second cap bank, and the n^{th} cap bank may include first to m^{th} switch-capacitor circuits which are connected in parallel with each other, wherein the first to m^{th} switch-capacitor circuits of the n^{th} cap bank may be configured to have different capacitances based on an n^{th} weight that is different from the first weight or the second weight, and wherein n is a natural number that is greater than or equal to 3.

Each of the first to m^{th} switch-capacitor circuits of the n^{th} cap bank may include a capacitor and a switch connected in series with each other.

Respective capacitors of the first to m^{th} switch-capacitor circuits of the n^{th} cap bank may be configured to have different capacitances based on the n^{th} weight.

In a general aspect, a capacitance variable circuit includes a capacitor circuit configured to have at least a first cap bank and a second cap bank; and a control circuit configured to control a change in capacitance of at least one of the first cap bank and the second cap bank, wherein the first cap bank includes first to m^{th} switch-capacitor circuits which are connected in parallel with each other, wherein the first to m^{th} switch-capacitor circuits are configured to have different capacitances based on a first weight, wherein the second cap bank is connected in parallel with the first cap bank, and includes first to m^{th} switch-capacitor circuits connected in parallel with each other, and wherein the first to m^{th} switch-capacitor circuits are configured to have different capacitances based on a second weight that is different from the first weight.

Each of the first to m^{th} switch-capacitor circuits of the first cap bank may include a capacitor and a switch connected in series with each other, and wherein respective capacitors of the first to m^{th} switch-capacitor circuits of the first cap bank may be configured to have different capacitances based on the first weight.

Each of the first to m^{th} switch-capacitor circuits of the second cap bank may include a capacitor and a switch connected in series with each other, and wherein respective capacitors of the first to m^{th} switch-capacitor circuits of the second cap bank may be configured to have different capacitances based on the second weight.

The capacitance variable circuit may further include a set of cap banks including the second cap bank to a n^{th} cap banks; wherein the n^{th} cap bank may be connected in parallel with the first cap bank or second cap bank, and the n^{th} cap bank may include first to m^{th} switch-capacitor circuits which may be connected in parallel with each other, wherein the first to m^{th} switch-capacitor circuits of the n^{th} cap bank may be configured to have different capacitances based on an n^{th} weight that is different from the first weight or the second weight, and wherein n is a natural number that is greater than or equal to 3.

Each of the first to m^{th} switch-capacitor circuits of the n^{th} cap bank may include a capacitor and a switch connected in series with each other.

Respective capacitors of the first to m^{th} switch-capacitor circuits of the n^{th} cap bank may be configured to have different capacitances based on the n^{th} weight.

The control circuit may include a switch controller configured to convert a received control bit into a switch control signal; and a cap switch buffer configured to select at least one cap bank from among a plurality of cap banks comprised in the capacitor circuit based on the switch control signal and to control a change in capacitance of the selected cap bank based on the switch control signal.

The switch controller may include a first decoder configured to generate a bank selection signal of the switch control signal based on an upper bit of the received control bit; and a second decoder configured to generate a capacitor selection signal of the switch control signal based on a lower bit of the control bit.

The cap switch buffer may include a first inverter device and a second inverter device which are connected in series.

The first inverter device and the second inverter device may be configured to transfer the bank selection signal of the switch control signal and the capacitor selection signal to a corresponding cap bank of the capacitor circuit.

In a general aspect, a capacitance circuit includes a control circuit; and a cap bank circuit comprising a plurality of cap banks connected in parallel with each other, each of the plurality of cap banks comprising a plurality of switch capacitor circuits connected in parallel with each other, wherein each of the plurality of switch capacitor circuits comprises a switch and a capacitor connected in series with each other, wherein each of the capacitors is configured to have different non-binary weighted capacitances; and wherein the control circuit is configured to select a cap bank of the plurality of cap banks based on a first control signal, and select one or more capacitors of the switch capacitor circuits based on a second control signal.

The control circuit may be configured to control a change in capacitance of the selected cap bank.

The control circuit may be configured to selectively turn on or turn off a switch of a selected switch capacitor circuit based on the second control signal.

Other features and aspects will be apparent from the following detailed description, the drawings, and the claims.

### BRIEF DESCRIPTION OF DRAWINGS

FIG. 1 illustrates an example capacitor circuit, in accordance with one or more embodiments.

FIG. 2 illustrates an example capacitor circuit, in accordance with one or more embodiments.

FIG. 3 illustrates an example capacitor circuit, in accordance with one or more embodiments.

FIG. 4 illustrates an example capacitance variable circuit, in accordance with one or more embodiments.

FIG. 5 illustrates an example capacitance variable circuit, in accordance with one or more embodiments.

FIG. 6 illustrates an example capacitance variable circuit, in accordance with one or more embodiments.

FIG. 7 illustrates an example switch controller, in accordance with one or more embodiments.

FIG. 8 illustrates an example cap switch buffer, in accordance with one or more embodiments.

FIG. 9 illustrates an example switch state table of a first cap bank depending on a switch control signal, in accordance with one or more embodiments.

FIG. 10 illustrates an example switch state table of a second cap bank depending on a switch control signal, in accordance with one or more embodiments.

FIG. 11 illustrates an example switch state table of a third cap bank depending on a switch control signal, in accordance with one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

Also, in the description of example embodiments, detailed description of structures or functions that are thereby known after an understanding of the disclosure of the present application will be omitted when it is deemed that such description will cause ambiguous interpretation of the example embodiments.

Hereinafter, examples will be described in detail with reference to the accompanying drawings, and like reference numerals in the drawings refer to like elements throughout.

One or more examples may provide a capacitor circuit in which each of a plurality of cap banks includes an array capacitor circuit and is implemented to have a different capacitance weight, and a capacitance variable circuit having the same.

In the one or more examples, the capacitance may be tuned in a tuning range of different capacitances for each cap bank by implementing each of a plurality of cap banks to include an array capacitor and each cap bank to have a different capacitance weight.

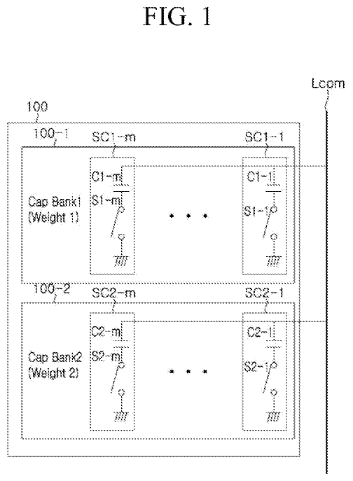

FIG. 1 illustrates an example capacitor circuit, in accordance with one or more embodiments.

Referring to FIG. 1, the example capacitor circuit may include a first cap bank 100-1 and a second cap bank 100-2.

The first cap bank 100-1 may include first to m^{th} switch-capacitor circuits SC1-1 to SC1-m (where m is a natural number that is equal to, or greater than, 2) which may be connected in parallel with each other.

The first to m^{th} switch-capacitor circuits SC1-1 to SC1-m of the first cap bank 100-1 may include different capacitances of, or based on, a first weight WT1.

The second cap bank 100-2 may be connected in parallel with the first cap bank 100-1, and may include first to m^{th} switch-capacitor circuits SC2-1 to SC2-m which are connected in parallel with each other.

The first to m^{th} switch-capacitor circuits SC1-1 to SC1-m of the first cap bank 100-1 may include different capacitances of, or based on, a second weight WT2 that is different from the first weight WT1.

Each of the first to m^{th} switch-capacitor circuits SC1-1 to SC1-m of the first cap bank 100-1 may include a capacitor and a switch which are connected in series with each other.

In an example, the first switch-capacitor circuit SC1-1 of the first cap bank 100-1 may include a first capacitor C1-1 and a first switch S1-1 which are connected in series with each other.

Additionally, the m^{th} switch-capacitor circuit SC1-m of the first cap bank 100-1 may include an m^{th} capacitor C1-m and an m^{th} switch S1-m which are connected in series with each other.

The first to m^{th} capacitors C1-1 and C1-2 to C1-m of the first cap bank 100-1 may be set to have different capacitances of, or based on, the first weight WT1.

In an example, the first weight WT1 is k1, the first capacitor C1-1 of the first cap bank 100-1 is k1*(2\hat{ }0) pF, and the m^{th} capacitor C1-m of the first cap bank 100-1 becomes k1*(2\hat{ }(m−1)) pF.

Each of the first to m^{th} switch-capacitor circuits SC2-1 to SC2-m of the second cap bank 100-2 may include a capacitor and a switch which are connected in series with each other.

In an example, the first switch-capacitor circuit SC2-1 of the second cap bank 100-2 may include a first capacitor C2-1 and a first switch S2-1 which are connected in series with each other.

Additionally, the m^{th} switch-capacitor circuit SC2-m of the second cap bank 100-2 may include an m^{th} capacitor C2-m and an m^{th} switch S2-m which are connected in series with each other.

The first to m^{th} capacitors C2-1 to C2-m of the second cap bank 100-2 may be set to have different capacitances based on the second weight WT2.

In an example, the second weight WT2 may be k2, the first capacitor C2-1 of the second cap bank 100-2 is k2*(2\hat{ }0), and the m^{th} capacitor C2-m of the first cap bank 100-1 becomes k2*(2\hat{ }(m−1)) pF.

FIG. 1 illustrates an example in which the capacitor circuit 100 includes two first and second cap banks 100-1 and 100-2. However, this is only an example, and the number of cap banks is not limited to two. In an example, the number of cap banks may be less than 2 or greater than two.

For each drawing of the one or more examples, unnecessary redundant descriptions of the same reference numerals and components having the same function may be omitted, and possible differences may be described for each drawing.

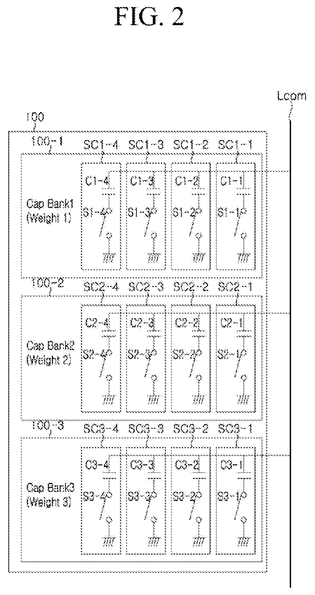

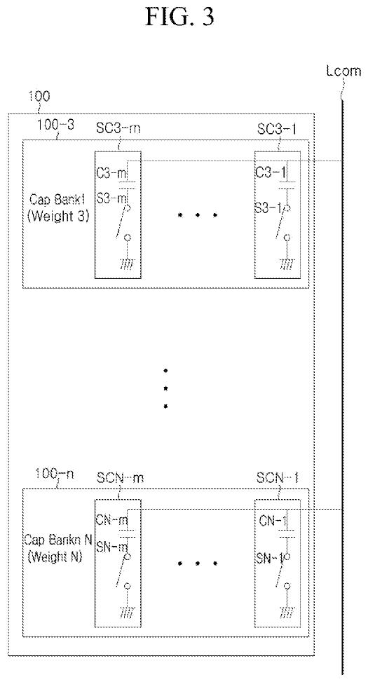

FIG. 2 illustrates an example capacitor circuit, in accordance with one or more embodiments, and FIG. 3 illustrates an example capacitor circuit, in accordance with one or more embodiments.

Referring to FIG. 2, the example capacitor circuit 100 may further include respective first, second, and third cap banks 100-1, 100-2, and 100-3.

The first cap bank 100-1 may include first to fourth switch-capacitor circuits SC1-1 to SC1-4.

In an example, the first switch-capacitor circuit SC1-1 of the first cap bank 100-1 may include a first capacitor C1-1 and a first switch S1-1 which are connected in series with each other. The second switch-capacitor circuit SC1-2 of the first cap bank 100-1 may include a second capacitor C1-2 and a third switch S1-2 which are connected in series with each other. The third switch-capacitor circuit SC1-3 of the first cap bank 100-1 may include a third capacitor C1-3 and a third switch S1-3 which are connected in series with each other. Additionally, the fourth switch-capacitor circuit SC1-4 of the first cap bank 100-1 may include a fourth capacitor C1-4 and a fourth switch S1-4 which are connected in series with each other.

The second cap bank 100-2 may include first to fourth switch-capacitor circuits SC2-1 to SC2-4.

In an example, the first switch-capacitor circuit SC2-1 of the second cap bank 100-2 may include a first capacitor C2-1 and a first switch S2-1 which are connected in series with each other. The second switch-capacitor circuit SC2-2 of the second cap bank 100-2 may include a second capacitor C2-2 and a second switch S2-2 which are connected in series with each other. The third switch-capacitor circuit SC2-3 of the second cap bank 100-2 may include a third capacitor C2-3 and a third switch S2-3 which are connected in series with each other. Additionally, the fourth switch-capacitor circuit SC2-4 of the second cap bank 100-2 may include a fourth capacitor C2-4 and a fourth switch S2-4 which are connected in series with each other.

The third cap bank 100-3 may include first to fourth switch-capacitor circuits SC3-1 to SC3-4.

In an example, the first switch-capacitor circuit SC3-1 of the third cap bank 100-3 may include a first capacitor C3-1 and a first switch S3-1 which are connected in series with each other. The second switch-capacitor circuit SC3-2 of the third cap bank 100-3 may include a second capacitor C3-2 and a second switch S3-2 which are connected in series with each other. The third switch-capacitor circuit SC3-3 of the third cap bank 100-3 may include a third capacitor C3-3 and a third switch S3-3 which are connected in series with each other. Additionally, the fourth switch-capacitor circuit SC3-4 of the third cap bank 100-3 may include a fourth capacitor C3-4 and a fourth switch S3-4 which are connected in series with each other.

FIG. 2 illustrates an example in which the capacitor circuit 100 includes three first to third cap banks 100-1, 100-2, and 100-3. However, this is only an example, and the examples are not limited to this example. Additionally, FIG. 2 illustrates examples in which each of the first, second, and third cap banks 100-1, 100-2, and 100-3 includes four first to fourth switch-capacitors. However, this is only an example, and the examples are not limited to these examples.

Referring to FIG. 3, the capacitor circuit 100 may further include third to n^{th} cap banks 100-3 to 100-n in the capacitor circuit of FIG. 1.

Referring again to FIG. 3, the third cap bank 100-3 may be connected in parallel to the first and second cap banks 100-1 and 100-2 (for example, the first and second cap banks 100-1 and 100-2 illustrated in FIG. 1), and may include first to m^{th} switch-capacitor circuits SC3-1 to SC3-m which are connected in parallel with each other.

The first to m^{th} switch-capacitor circuits SC3-1 to SC3-m of the third cap bank 100-3 may be set to have different capacitances based on a third weight WT3 that is different from the first and second weights WT1 and WT2.

Referring to FIG. 3, the n^{th} cap bank 100-n may include first to m^{th} switch-capacitor circuits SCn1 to SCn-m connected in parallel to other cap banks such as the first to third cap banks 100-1, 100-2, and 100-3, and connected in parallel with each other.

The first to m^{th} switch-capacitor circuits SCn-1 to SCn-m of the n^{th} cap bank 100-n may include different capacitances of an n^{th} weight WTn that is different from the first to third weights WT1 to WT3.

Each of the first to m^{th} switch-capacitor circuits SC3-1 to SC3-m of the third cap bank 100-3 may include a capacitor and a switch which are connected in series with each other.

In an example, the first switch-capacitor circuit SC3-1 of the third cap bank 100-3 may include a first capacitor C3-1 and a first switch S3-1 which are connected in series with each other.

Additionally, the m^{th} switch-capacitor circuit SC3m of the third cap bank 100-3 may include an m^{th} capacitor C3-m and an m^{th} switch S3-m which are connected in series with each other.

The first to m^{th} capacitors C3-1 to C3-m of the third cap bank 100-3 may be set to have different capacitances based on the third weight WT3.

In an example, the third weight WT3 is k3, the third capacitor C3-1 of the third cap bank 100-3 is k3*(2\hat{ }0), and the m^{th} capacitor C3-m of the third cap bank 100-3 becomes k3*(2\hat{ }(m−1)) pF.

Each of the first to m^{th} switch-capacitor circuits SCN-1 to SCN-m of the N^{th} cap bank 100-N may include a capacitor and a switch which are connected in series with each other.

In an example, the first switch-capacitor circuit SCN-1 of the N^{th} cap bank 100-N may include a first capacitor CN-1 and a first switch SN-1 which are connected in series with each other.

Additionally, the m^{th} switch-capacitor circuit SCN-m of the N^{th} cap bank 100-N may include an m^{th} capacitor CN-m and an m^{th} switch SN-m which are connected in series with each other.

Each of the first to m^{th} switch-capacitor circuits SCn-1 to SCn-m of the n^{th} cap bank 100-n is a capacitor which may be set to have different capacitances based on the N^{th} weight WTN.

In an example, the third weight WTN is kN, the third capacitor CN-1 of the N^{th} cap bank 100-N is kN*(2\hat{ }0), and the m^{th} capacitor CN-m of the N^{th} cap bank 100-N is kN*(2\hat{ }(m−1)) pF.

In one or more examples, the first weight WT1, the second weight WT2, and the N^{th} weight WTN are weights to set different capacitances, and may be binary weights as in the example above, but the one or more examples are not limited thereto, and may be a variety of weights, such as double weights and triple weights, and they are not limited to a specific multiple relationship as long as different weights are applied for each bank.

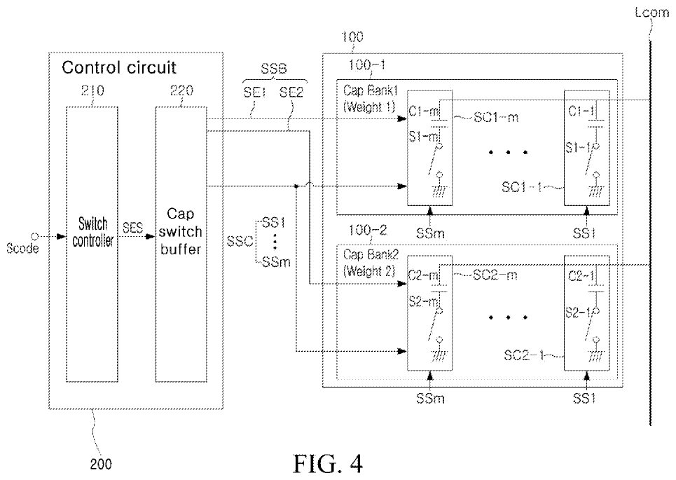

FIG. 4 illustrates an example capacitance variable circuit, in accordance with one or more embodiments.

Referring to FIG. 4, an example capacitance variable circuit may include a cap bank circuit 100 including at least a first cap bank 100-1 and a second cap bank 100-2, and a control circuit 200 that controls a variation of a capacitance of the cap bank circuit 100.

The first cap bank 100-1 may include first to m^{th} switch-capacitor circuits SC1-1 to SC1-m which are connected in parallel with each other.

The first to m^{th} switch-capacitor circuits SC1-1 to SC1-m may include different capacitances based on a first weight WT1.

The second cap bank 100-2 may be connected in parallel to the first cap bank 100-1, and may include first to m^{th} switch-capacitor circuits SC2-1 to SC2-m which are connected in parallel with each other.

The second to m^{th} switch-capacitor circuits SC1-1 to SC1-m may include different capacitances based on a second weight WT2 that is different from the first weight WT1.

The control circuit 200 may select at least one of the first and second cap banks included in the cap bank circuit 100, and may control a change in capacitance of the selected cap bank.

Each of the first to m^{th} switch-capacitor circuits SC1-1 to SC1-m of the first cap bank 100-1 may include a capacitor and a switch which are connected in series with each other.

In an example, the first switch-capacitor circuit SC1-1 of the first cap bank 100-1 may include a first capacitor SC1-1 and a first switch S1-1 which are connected in series with each other.

Additionally, the m^{th} switch-capacitor circuit SC1-m of the first cap bank 100-1 may include an m^{th} capacitor C1-m and an m^{th} switch S1-m which are connected in series with each other.

The first to m^{th} capacitors C1-1 to C1-m of the first to m^{th} switch-capacitor circuits SC1-1 to SC1-m of the first cap bank 100-1 may be set to have different capacitances based on the first weight WT1.

In an example, the first weight WT1 is k1, the first capacitor C1-1 of the first cap bank 100-1 is k1*(2\hat{ }0) pF, the second capacitor C1-2 of the first cap bank 100-1 is k1*(2\hat{ }1) pF, and the m^{th} capacitor C1-m of the first cap bank 100-1 becomes k1*(2\hat{ }(m−1)) pF.

Each of the first to m^{th} switch-capacitor circuits SC2-1 to SC2-m of the second cap bank 100-2 may include a capacitor and a switch which are connected in series to each other.

In an example, the first switch-capacitor circuit SC2-1 of the second cap bank 100-2 may include a first capacitor C2-1 and a first switch S2-1 which are connected in series with each other.

Additionally, the m^{th} switch-capacitor circuit SC2-m of the second cap bank 100-2 may include an m^{th} capacitor C2-m and an m^{th} switch S2-m which are connected in series with each other.

Each of the first to m^{th} capacitors of the first to m^{th} switch-capacitor circuits SC2-1 to SC2-m of the second cap bank 100-2 may be set to have different capacitances based on the second weight WT2.

In an example, the second weight WT2 is k2, the first capacitor C2-1 of the second cap bank 100-2 is k2*(2\hat{ }0), the second capacitor C2-2 of the first cap bank 100-1 is k2*(2\hat{ }1) pF, and the m^{th} capacitor C1-m of the first cap bank 100-1 becomes k2*(2\hat{ }(m−1)) pF.

FIG. 4 illustrates an example in which the capacitor circuit 100 includes two first and second cap banks 100-1 and 100-2, but this is only an example for convenience of description, and the one or more examples are not limited to this example.

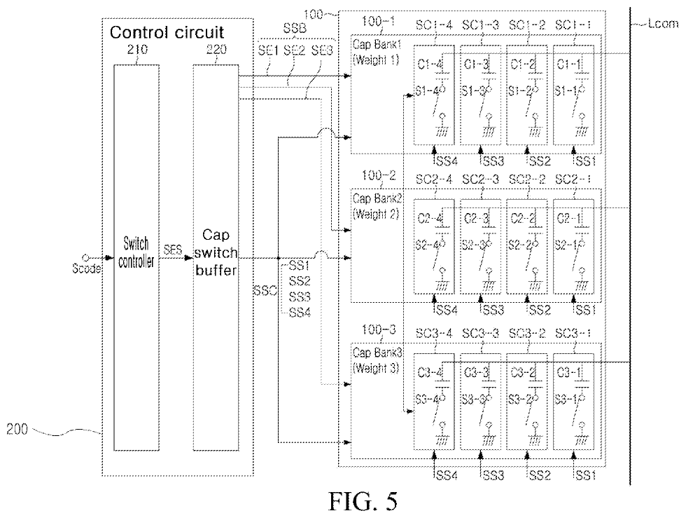

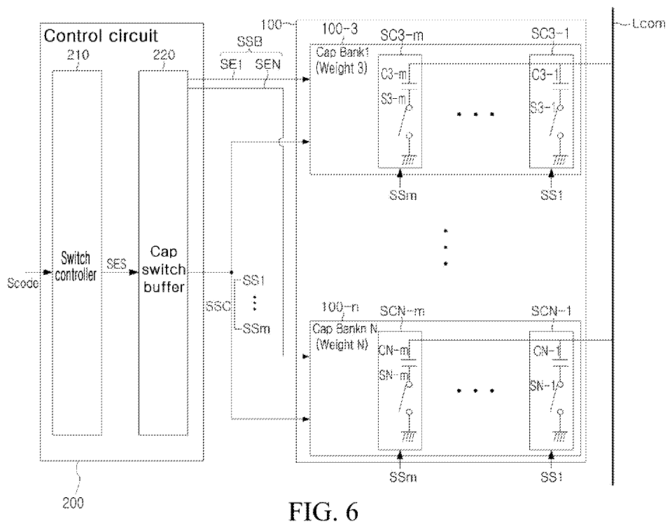

FIG. 5 illustrates an example capacitance variable circuit, in accordance with one or more embodiments, and FIG. 6 illustrates an example capacitance variable circuit, in accordance with one or more embodiments.

Referring to FIG. 5, the capacitor circuit 100 may further include first, second, and third cap banks 100-1, 100-2, and 100-3.

The first cap bank 100-1 may include first to fourth switch-capacitor circuits SC1-1 to SC1-4.

In an example, the first switch-capacitor circuit SC1-1 of the first cap bank 100-1 may include a first capacitor C1-1 and a first switch S1-1 which are connected in series with each other. The second switch-capacitor circuit SC1-2 of the first cap bank 100-1 may include a second capacitor C1-2 and a third switch S1-2 which are connected in series with each other. The third switch-capacitor circuit SC1-3 of the first cap bank 100-1 may include a third capacitor C1-3 and a third switch S1-3 which are connected in series with each other. Additionally, the fourth switch-capacitor circuit SC1-4 of the first cap bank 100-1 may include a fourth capacitor C1-4 and a fourth switch S1-4 which are connected in series with each other.

Each of the respective first to fourth switches S1-1 to S1-4 of the first cap bank 100-1 may be turned on or turned off in response to a capacitor selection signal SSC from the control circuit 200.

The second cap bank 100-2 may include first to fourth switch-capacitor circuits SC2-1 to SC2-4.

In an example, the first switch-capacitor circuit SC2-1 of the second cap bank 100-2 may include a first capacitor C2-1 and a first switch S2-1 which are connected in series with each other. The second switch-capacitor circuit SC2-2 of the second cap bank 100-2 may include a second capacitor C2-2 and a second switch S2-2 which are connected in series with each other. The third switch-capacitor circuit SC2-3 of the first cap bank 100-2 may include a third capacitor C2-3 and a third switch S2-3 which are connected in series with each other. Additionally, the fourth switch-capacitor circuit SC2-4 of the second cap bank 100-2 may include a fourth capacitor C2-4 and a fourth switch S2-4 which are connected in series with each other.

Each of the first to fourth switches S2-1 to S2-4 of the second cap bank 100-2 may be turned on or turned off in response to the capacitor selection signal SSC from the control circuit 200.

The third cap bank 100-3 may include first to fourth switch-capacitor circuits SC3-1 to SC3-4.

In an example, the first switch-capacitor circuit SC3-1 of the third cap bank 100-3 may include a first capacitor C3-1 and a first switch S3-1 which are connected in series with each other. The second switch-capacitor circuit SC3-2 of the third cap bank 100-3 may include a second capacitor C3-2 and a second switch S3-2 which are connected in series with each other. The third switch-capacitor circuit SC3-3 of the third cap bank 100-3 may include a third capacitor C3-3 and a third switch S3-3 which are connected in series with each other. Additionally, the fourth switch-capacitor circuit SC3-4 of the third cap bank 100-3 may include a fourth capacitor C3-4 and a fourth switch S3-4 which are connected in series with each other.

Each of the first to fourth switches S2-1 to S2-4 of the third cap bank 100-3 may be turned on or turned off in response to the capacitor selection signal SSC from the control circuit 200.

FIG. 5 illustrates an example in which the capacitor circuit 100 includes three first and third cap banks 100-1, 100-2, and 100-3. However, this is only an example, and the one or more embodiments are not limited to this example.

Referring to FIG. 6, the example capacitor circuit 100 may further include third to n^{th} cap banks 100-3 to 100-n in the capacitor circuit of FIG. 4.

Referring to FIG. 6, the third cap bank 100-3 may be connected in parallel with the first and second cap banks 100-1 and 100-2 (for example, the first and second cap banks 100-1 and 100-2 illustrated in FIG. 4), and may include first to m^{th} switch-capacitor circuits SC3-1 to SC3-m which are connected in parallel with each other.

The first to m^{th} switch-capacitor circuits SC3-1 to SC3-m of the third cap bank 100-3 may be set to have different capacitances based on a third weight WT3 that is different from the first and second weights WT1 and WT2.

The n^{th} cap bank 100-n may include first to m^{th} switch-capacitor circuits SCN1 to SCN-m connected in parallel with other cap banks such as the first to third cap banks 100-1, 100-2, and 100-3, and connected in parallel with each other.

The first to m^{th} switch-capacitor circuits SCN-1 to SCN-m of the n^{th} cap bank 100-n may include different capacitances based on an n^{th} weight WTn that is different from the first to third weights WT1 to WT3.

Each of the first to m^{th} switch-capacitor circuits SC3-1 to SC3-m of the third cap bank 100-3 may include a capacitor and a switch which are connected in series with each other.

In an example, the first switch-capacitor circuit SC3-1 of the third cap bank 100-3 may include a first capacitor C3-1 and a first switch S3-1 which are connected in series with each other.

Additionally, the m^{th} switch-capacitor circuit SC3m of the third cap bank 100-3 may include an m^{th} capacitor C3-m and an m^{th} switch S3-m which are connected in series with each other.

The first to m^{th} capacitors C3-1 to C3-m of the third cap bank 100-3 may be set to have different capacitances based on the third weight WT3.

In an example, the third weight WT3 is k3, the third capacitor C3-1 of the third cap bank 100-3 is k3*(2\hat{ }0), and the m^{th} capacitor C3-m of the third cap bank 100-3 becomes k3*(2\hat{ }(m−1)) pF.

Each of the first to m^{th} switch-capacitor circuits SCN-1 to SCN-m of the N^{th} cap bank 100-N may include a capacitor and a switch which are connected in series with each other.

In an example, the first switch-capacitor circuit SCN-1 of the N^{th} cap bank 100-N may include a first capacitor CN-1 and a first switch SN-1 which are connected in series with each other.

Additionally, the m^{th} switch-capacitor circuit SCN-m of the N^{th} cap bank 100-N may include an m^{th} capacitor CN-m and an m^{th} switch SN-m which are connected in series with each other.

Each of the first to m^{th} switch-capacitor circuits SCn-1 to SCn-m of the n^{th} cap bank 100-n may be a capacitor that may be set to have different capacitances based on the N^{th} weight WTN.

In an example, the third weight WTN is kN, the third capacitor CN-1 of the N^{th} cap bank 100-N is kN*(2\hat{ }0), and the m^{th} capacitor CN-m of the N^{th} cap bank 100-N is kN*(2\hat{ }(m−1)) pF.

Referring to FIG. 4 to FIG. 6, the control circuit 200 may include a switch controller 210 and a cap switch buffer 220.

The switch controller 210 may convert a received control bit Scode into a switch control signal SES including a bank selection signal SSB to select at least one bank from among banks included in the capacitor circuit 100 based on the received control bit Scode and a capacitor selection signal SSC to control a change in capacitance of a corresponding bank selected based on the control bit Scode.

The cap switch buffer 220 may transmit the bank selection signal SSB and the capacitor selection signal SSC of the switch control signal SES from the switch control signal SES to the corresponding bank.

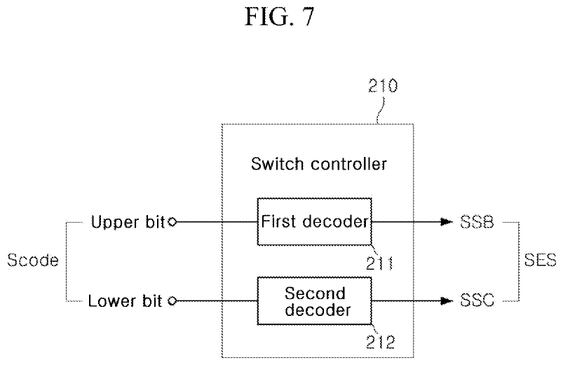

FIG. 7 illustrates an example switch controller, in accordance with one or more embodiments.

Referring to FIG. 7, the switch controller 210 may include a first decoder 211 and a second decoder 212.

The first decoder 211 may generate the bank selection signals SSB (SSB1 to SSBn) of the switch control signal SES based on an upper bit of the received control bit Scode.

The second decoder 212 may generate the capacitor selection signals SSC (SSC1 to SSCm) of the switch control signal SES based on a lower bit of the control bit Scode.

In an example, when the control bit Scode is 6 bits including two upper bits (2\hat{ }5 and 2\hat{ }4) and four lower bits (2\hat{ }3, 2\hat{ }2, 2\hat{ }1, and 2\hat{ }0), the first decoder 211 may generate the bank selection signals SSB (SSB1 to SSBn) based on two upper bits (2\hat{ }5 and 2\hat{ }4).

The second decoder 212 may generate the capacitor selection signals SSC (SSC1 to SSCm) based on four lower bits (2\hat{ }3, 2\hat{ }2, 2\hat{ }1, and 2\hat{ }0).

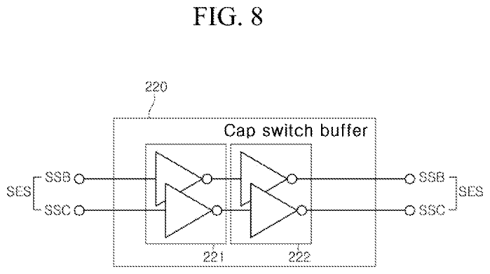

FIG. 8 illustrates an example of a cap switch buffer, in accordance with one or more embodiments.

Referring to FIG. 8, the example cap switch buffer 220 may include a first inverter device 221 and a second inverter device 222 which are connected in series.

The first inverter device 221 and the second inverter device 222 may transmit the bank selection signals SSB1 to SSBn and the capacitor selection signals SSC1 to SSCm of the switch control signal SES to corresponding cap banks 100-1 and 100-2 of the capacitor circuit 100.

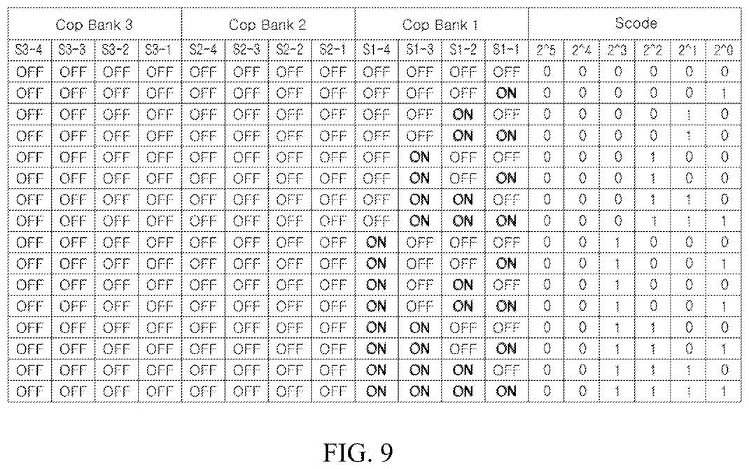

Hereinafter, as illustrated in FIG. 3, the capacitor circuit 100 may include first, second, and third cap banks 100-1, 100-2, and 100-3, and a switching on or switching off state depending on the switch control signal Scode for an example where the first, second, and third cap banks 100-1, 100-2, and 100-3 respectively include first, second, third, and fourth switches SC1-1 to SC1-4, SC2-1 to SC2-4, SC3-1 to SC3-4, and SC4-1 to SC4-4 will be described with reference to FIG. 9 to FIG. 11.

Additionally, as illustrated in FIG. 4 to FIG. 6, the bank selection signal SSB may include first to m^{th} bank selection signals SE1 to SEm.

In an example, when the first bank selection signal SE1 is at a high level, the first cap bank 100-1 may be selected, and when the m^{th} bank selection signal SEm is at a high level, the m^{th} cap bank 100-m may be selected.

Referring to FIG. 8, the cap switch buffer 220 may include two inverters which are connected in series to perform a buffer function, which is only an example, and the one or more examples are not limited thereto.

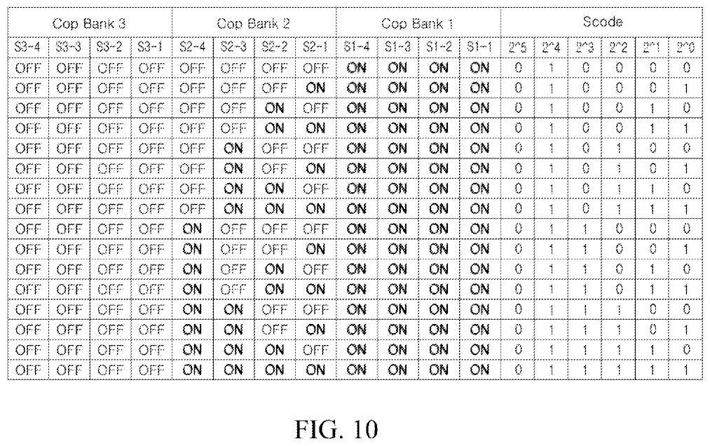

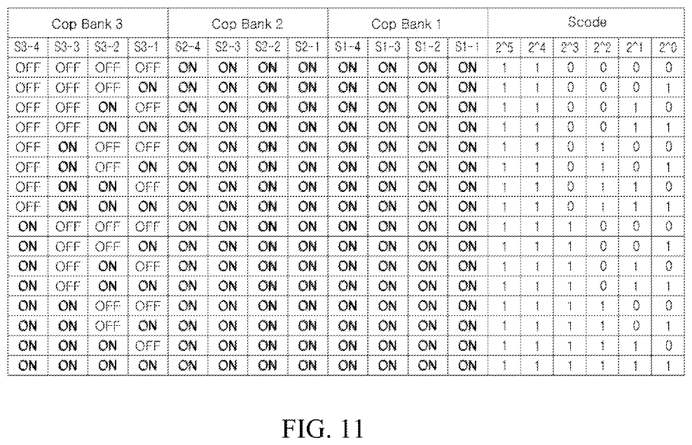

Hereinafter, FIG. 9, FIG. 10, and FIG. 11 are based on the circuit illustrated in FIG. 5, and the control bit Scode will be described as an example of 6 bits including two upper bits (2\hat{ }5 and 2\hat{ }4) and four lower bits (2\hat{ }3, 2\hat{ }2, 2\hat{ }1, and 2\hat{ }0).

FIG. 9 illustrates an example switch state table of a first cap bank depending on a switch control signal, in accordance with one or more embodiments.

Referring to FIG. 9, the first cap bank 100-1 may be selected by a first bank selection signal SE1 of the bank selection signal SSB based on a logic state 00 of the two upper bits (2\hat{ }5 and 2\hat{ }4) in the 6-bit switch control signal Scode. In this example, depending on the capacitor selection signal SSC based on a logic state of the four lower bits (2\hat{ }3, 2\hat{ }2, 2\hat{ }1, and 2\hat{ }0) in the 6-bit switch control signal Scode, as illustrated in FIG. 9, the four switches S1-1, S1-2, S1-3, and S1-4 may be controlled in different switching states, and thus the capacitance may be varied.

In this example, all switches of the second and third cap banks 100-2 and 100-3 may be in an off state depending on second and third bank selection signals SE2 and SE3 of the bank selection signal SSB based on the logic state 00 of the two upper bits (2\hat{ }5 and 2\hat{ }4) in the 6-bit switch control signal Scode.

FIG. 10 illustrates an example switch state table of a second cap bank depending on a switch control signal, in accordance with one or more embodiments.

Referring to FIG. 10, for the first cap bank 100-1, all switches may be turned on by the first bank selection signal SE1 of the bank selection signal SSB based on a logic state 01 of the two upper bits (2\hat{ }5 and 2\hat{ }4) in the 6-bit switch control signal Scode.

The second cap bank 100-2 may be selected by a second bank selection signal SE2 of the bank selection signal SSB based on a logic state 01 of the two upper bits (2\hat{ }5 and 2\hat{ }4) in the 6-bit switch control signal Scode. In this example, depending on the capacitor selection signal SSC based on a logic state of the four lower bits (2\hat{ }3, 2\hat{ }2, 2\hat{ }1, and 2\hat{ }0) in the 6-bit switch control signal Scode, as illustrated in FIG. 10, the four switches S2-1, S2-2, S2-3, and S2-4 are controlled in different switching states, and thus the capacitance may be varied.

In this example, all the switches of the third cap bank 100-3 may be in an off state depending on the third bank selection signal SE3 of the bank selection signal SSB based on the logic state 01 of the two upper bits (2\hat{ }5 and 2\hat{ }4) in the 6-bit switch control signal Scode.

FIG. 11 illustrates an example switch state table of a third cap bank depending on a switch control signal, in accordance with one or more embodiments.

Referring to FIG. 11, for the first and second cap banks 100-1 and 100-2, all switches may be turned on by the first and second bank selection signals SE1 and SE2 of the bank selection signal SSB based on a logic state 11 of the two upper bits (2\hat{ }5 and 2\hat{ }4) in the 6-bit switch control signal Scode.

The third cap bank 100-2 may be selected by a first bank selection signal SE3 of the bank selection signal SSB based on a logic state 11 of the two upper bits (2\hat{ }5 and 2\hat{ }4) in the 6-bit switch control signal Scode. In this example, depending on the capacitor selection signal SSC based on a logic state of the four lower bits (2\hat{ }3, 2\hat{ }2, 2\hat{ }1, and 2\hat{ }0) in the 6-bit switch control signal Scode, as illustrated in FIG. 11, the four switches S2-1, S2-2, S2-3, and S2-4 are controlled in different switching states, and thus the capacitance may be varied.

In an example, the switch control circuit 200 of the example capacitance variable circuit may be implemented as a computing environment in which a processor (e.g., a central processing unit (CPU), a graphics processing unit (GPU), a microprocessor, an application specific integrated circuit (ASIC), a field programmable gate array (FPGA), etc.), a memory (e.g., a volatile memory (e.g., a RAM, etc.)), a non-volatile memory (e.g., a ROM, a flash memory, etc.), an input device (e.g., a keyboard, a mouse, a pen, a voice input device, a touch input device, an infrared camera, a video input device, etc.), an output device (e.g., a display, a speaker, a printer, etc.), and a communication connection device (e.g., a modem, a network interface card (NIC)), an integrated network interface, a radio frequency transmitter/receiver, an infrared port, a USB interface, etc.) are interconnected (using, e.g., a peripheral component interconnection (PCI), a USB, firmware (IEEE 1394), an optical bus structure, a network, etc.).

The computing environment may be implemented as a personal computer, a server computer, a handheld or laptop device, a mobile device (e.g., a mobile phone, a PDA, a media player, etc.), a multiprocessor system, consumer electronics, a minicomputer, a mainframe computer, a distributed computing environment including any of the foregoing systems or devices, etc., but the examples are not limited thereto.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A multi-bank array type capacitor circuit, comprising:
a first cap bank comprising first to m^{th} switch-capacitor circuits connected in parallel with each other, wherein the first to m^{th} switch-capacitor circuits are configured to have different capacitances based on a first weight; and
a second cap bank connected in parallel with the first cap bank, and comprising first to m^{th} switch-capacitor circuits which are connected in parallel with each other, wherein the first to m^{th} switch-capacitor circuits are configured to have different capacitances based on a second weight that is different from the first weight,
wherein m is a natural number equal to or greater than 2.

2. The capacitor circuit of claim 1, wherein each of the first to m^{th} switch-capacitor circuits of the first cap bank comprises a capacitor and a switch connected in series with each other, and
wherein respective capacitors of the first to m^{th} switch-capacitor circuits of the first cap bank are configured to have different capacitances based on the first weight.

3. The capacitor circuit of claim 1, wherein each of the first to m^{th} switch-capacitor circuits of the second cap bank comprises a capacitor and a switch connected in series with each other, and
wherein respective capacitors of the first to m^{th} switch-capacitor circuits of the second cap bank are configured to have different capacitances based on the second weight.

4. The capacitor circuit of claim 1, further comprising a set of cap banks comprising the second cap bank to a n^{th} cap bank;
wherein the n^{th} cap bank is connected in parallel with the first cap bank or the second cap bank, and the n^{th} cap bank comprises first to m^{th} switch-capacitor circuits which are connected in parallel with each other,
wherein the first to m^{th} switch-capacitor circuits of the n^{th} cap bank are configured to have different capacitances based on an n^{th} weight that is different from the first weight or the second weight, and
wherein n is a natural number that is greater than or equal to 3.

5. The capacitor circuit of claim 4, wherein each of the first to m^{th} switch-capacitor circuits of the n^{th} cap bank comprises a capacitor and a switch connected in series with each other.

6. The capacitor circuit of claim 4, wherein respective capacitors of the first to m^{th} switch-capacitor circuits of the n^{th} cap bank are configured to have different capacitances based on the n^{th} weight.

7. A capacitance variable circuit comprising:
a capacitor circuit configured to have at least a first cap bank and a second cap bank; and
a control circuit configured to control a change in capacitance of at least one of the first cap bank and the second cap bank,
wherein the first cap bank comprises first to m^{th} switch-capacitor circuits which are connected in parallel with each other, wherein the first to m^{th} switch-capacitor circuits are configured to have different capacitances based on a first weight,
wherein the second cap bank is connected in parallel with the first cap bank, and comprises first to m^{th} switch-capacitor circuits connected in parallel with each other, and
wherein the first to m^{th} switch-capacitor circuits are configured to have different capacitances based on a second weight that is different from the first weight.

8. The capacitance variable circuit of claim 7, wherein each of the first to m^{th} switch-capacitor circuits of the first cap bank comprises a capacitor and a switch connected in series with each other, and
wherein respective capacitors of the first to m^{th} switch-capacitor circuits of the first cap bank are configured to have different capacitances based on the first weight.

9. The capacitance variable circuit of claim 7, wherein each of the first to m^{th} switch-capacitor circuits of the second cap bank comprises a capacitor and a switch connected in series with each other, and
wherein respective capacitors of the first to m^{th} switch-capacitor circuits of the second cap bank are configured to have different capacitances based on the second weight.

10. The capacitance variable circuit of claim 7, further comprising a set of cap banks comprising the second cap bank to a n^{th} cap banks;
wherein the n^{th} cap bank is connected in parallel with the first cap bank or second cap bank, and the n^{th} cap bank comprises first to m^{th} switch-capacitor circuits which are connected in parallel with each other,
wherein the first to m^{th} switch-capacitor circuits of the n^{th} cap bank are configured to have different capacitances based on an n^{th} weight that is different from the first weight or the second weight, and
wherein n is a natural number that is greater than or equal to 3.

11. The capacitance variable circuit of claim 10, wherein each of the first to m^{th} switch-capacitor circuits of the n^{th} cap bank comprises a capacitor and a switch connected in series with each other.

12. The capacitance variable circuit of claim 10, wherein respective capacitors of the first to m^{th} switch-capacitor circuits of the n^{th} cap bank are configured to have different capacitances based on the n^{th} weight.

13. The capacitance variable circuit of claim 10, wherein the control circuit comprises:
a switch controller configured to convert a received control bit into a switch control signal; and
a cap switch buffer configured to select at least one cap bank from among a plurality of cap banks comprised in the capacitor circuit based on the switch control signal and to control a change in capacitance of the selected cap bank based on the switch control signal.

14. The capacitance variable circuit of claim 13, wherein the switch controller comprises:
a first decoder configured to generate a bank selection signal of the switch control signal based on an upper bit of the received control bit; and
a second decoder configured to generate a capacitor selection signal of the switch control signal based on a lower bit of the control bit.

15. The capacitance variable circuit of claim 14, wherein the cap switch buffer comprises a first inverter device and a second inverter device which are connected in series.

16. The capacitance variable circuit of claim 15, wherein the first inverter device and the second inverter device are configured to transfer the bank selection signal of the switch control signal and the capacitor selection signal to a corresponding cap bank of the capacitor circuit.

17. A capacitance circuit, comprising:
a control circuit; and
a cap bank circuit comprising a plurality of cap banks connected in parallel with each other, each of the plurality of cap banks comprising a plurality of switch capacitor circuits connected in parallel with each other,
wherein each of the plurality of switch capacitor circuits comprises a switch and a capacitor connected in series with each other,
wherein each of the capacitors is configured to have different non-binary weighted capacitances; and
wherein the control circuit is configured to select a cap bank of the plurality of cap banks based on a first control signal, and select one or more capacitors of the switch capacitor circuits based on a second control signal.

18. The capacitance circuit of claim 17, wherein the control circuit is configured to control a change in capacitance of the selected cap bank.

19. The capacitance circuit of claim 18, wherein the control circuit is configured to selectively turn on or turn off a switch of a selected switch capacitor circuit based on the second control signal.
